(19) United States
(12) Patent Application Publication
(10) Pub. No.: US 2013/0140173 A1
(43) Pub. Date: Jun. 6, 2013

(54) ROTARY SPUTTER TARGET ASSEMBLY

(71) Applicants: Séverin Stéphane Gérard Tierce, Montaut (FR); Paul S. Gilman, Suffern, NY (US)

(72) Inventors: Séverin Stéphane Gérard Tierce, Montaut (FR); Paul S. Gilman, Suffern, NY (US)

(21) Appl. No.: 13/489,583

(22) Filed: Jun. 6, 2012

Related U.S. Application Data
(60) Provisional application No. 61/495,509, filed on Jun. 10, 2011.

(51) Int. Cl. B21D 39/04; C23C 14/34

(52) U.S. Cl. CPC B21D 39/04; C23C 14/34
USPC 204/298.12; 29/825

(57) ABSTRACT

This invention utilizes a co-extrusion or co-drawing process to directly bond a tubular target to an inner backing tube. The co-extrusion or co-drawing process reduces the inner and outer diameters of the outer tubular target to cause portions of the target to protrude and at least partially fill into grooves along the inner backing tube. The filling causes the target to interlock to the backing plate.

### CROSS REFERENCE TO RELATED APPLICATIONS

This application claims the benefit of U.S. Provisional Application Ser. No. 61/495,509, filed Jun. 10, 2011, the disclosure of which is herein incorporated by reference in its entirety.

### FIELD OF THE INVENTION

This invention relates generally to the field of sputter targets. In particular, embodiments of this invention relate to improved rotary sputter target assemblies where the target is directly joined to a backing tube through a co-drawing or co-extrusion process.

### BACKGROUND OF THE INVENTION

Cathodic sputtering is widely used for the deposition of thin materials of conductive material onto desired substrates. This process requires a gas ion bombardment of a target formed of a desired material that is to be deposited as a thin film onto a substrate. Ion bombardment of a surface of the target causes atoms or ions of the target material to be sputtered. The target forms a part of a cathode assembly with an anode. The cathode assembly is placed in an evacuated chamber filled with an inert gas, preferably argon. A high voltage electrical field is applied across the cathode and the anode. The inert gas is ionized by collisions with electrons ejected from the cathode to form positively charged gas ions. The positively charged gas ions are attracted to the cathode. Upon impingement with the target surface, these ions dislodge the target material. The dislodged target material traverses the evacuated enclosure and deposits as a film on the desired substrate, which is normally located close to the anode.

Planar and rotary type targets are the two main types of sputtering targets. Planar targets are generally defined as a rectangular-shaped targets supported onto a rectangular-shaped backing plates. Rotary targets include tubular-shaped targets with or without backing tubes. The tubular targets are elongated and cylindrically-shaped, characterized by a hollow interior that is surrounded by a predetermined wall thickness.

Large area coatings, such as architectural glass, onto high area substrates require high rates of coating speed and long life of the targets to lower manufacturing costs and reduce downtime of the systems. Rotary targets are known to achieve a higher deposition rate and higher target utilization efficiency compared to planar targets. As a result, the sputtering of rotary targets, as opposed to planar targets, can be suitable for producing the large area coatings.

Several techniques are utilized to assemble tubular targets. One technique known in the art includes bonding of the active portion of the target (i.e., the portion of the target which is consumed during the sputtering process) onto a backing tube using an interlayer material. In one example, indium can be used as a solder-bonding interlayer material. However, because of indium's low melting temperature, it can only withstand a low amount of thermal stress. The sputtering process tends to produce power density levels that result in temperatures exceeding the melting point of indium and other low melting point bonding materials.

Moreover, these power density levels generated during sputtering can cause the rotary target assembly to attain a higher temperature than in sputtering methods utilizing planar targets. The higher temperatures can disrupt the bond formed between the tubular target and the backing tube. For instance, if the tubular target is solder-bonded to the backing tube, the heat developed during the sputtering process can be sufficient to melt the solder bond and debond the target free from the backing tube. Accordingly, solder-bonding, while often suitable for planar targets, can be problematic for rotary targets. The bond between the tubular target and backing tube must be thermally conductive and be able to accommodate or prevent residual stresses encountered during the sputtering process.

In addition, conventional solder or braze bonding can be difficult when being used as an interlayer material for joining temperature-sensitive materials, in which a physical property of the materials (e.g., microstructural grain size, hardness, yield strength, tensile strength, electrical conductivity and thermal conductivity) changes an appreciable amount when heated. Such materials may include metals, alloys, ceramics and polymers. Other physical properties include the dimensions or shape of the material. For example, a metal tube may contain considerable residual stress. Upon heating, the metallic tube may bend or warp and remain deformed upon cooling. Noteworthy temperature-sensitive materials include alloys that can be strengthened by cold work or heat treatment such as aluminum alloys (e.g., the 5000 and 6000 series of aluminum alloys) and copper alloys.

Another technique known for tubular target preparation is to take a monoblock tube and affix end fittings to one or both ends to one or both end portions of the active part of the target. The end fittings may be affixed by electron beam welding, mechanical assembly or any other suitable assembly method. Specific surface treatment may be applied to the inner side of the active part of the target to enhance its corrosion resistance, thereby allowing the monoblock tube to remain structurally intact and accommodate the various thermal and mechanical stresses generated during the sputtering process. For instance, the inner side of a pure aluminum tubular active target can be anodized to produce a hardened surface coating. However, this type of manufacturing process is typically costly, time consuming and complex as it involves the steps of affixing end fittings to one or both end portions of the target, applying a specific treatment on the inner side of the active part of the target and machining

Some target materials can be easily destroyed during manufacturing due to a variety of reasons including but not limited to brittleness, thermal sensitivity, low impact strength, bonding failures and differing rates of thermal expansion. Additionally, in the sputtering process, cycling temperatures, vacuum conditions, high sputter surface plasma temperatures, fixturing integrity, liquid cooling of the rotary tube, high operating power levels, and other parameters can all contribute to the failure or premature failure of the rotary target assembly.

Furthermore, tubular targets that are joined to inner backing tubes often prematurely fail during the sputtering process. In particular, during sputtering, separation of the tubular target and the backing tube at the bonded interface can occur as a result of the difference in thermal expansion coefficient between the tubular target and the backing tube. Such a separation of material compounds the inability of the target to dissipate heat. As a result, the exposed target surface continues to increase in surface temperature, thereby worsening separation of the target from the backing tube. Warpage and ultimately debonding can result.

It would be desirable to develop improved methods to assemble tubular targets to backing tubes. Further, the ability to simplify the process for making a rotary target assembly and at the same time improve the structural integrity of the bonded target assembly is desirable. Other aspects of the present invention will become apparent to one of ordinary skill in the art upon review of the specification, drawings, and claims appended hereto.

### SUMMARY OF THE INVENTION

The present invention utilizes a co-extrusion or co-drawing process to directly bond a tubular target to an inner backing tube by formation of a grooved interface. The co-extrusion or co-drawing process reduces the inner and outer diameters of the outer target material to cause portions of the target to protrude and at least partially fill into grooves disposed along the periphery of an inner backing tube. The target interlocks to the backing tube to form the grooved interface.

In a first aspect, a rotatable sputter target assembly is provided. The assembly comprises a backing tube comprising an outer surface. A sputtering tubular target is also provided comprising an inner surface. The inner surface is in direct contact with the outer surface of the backing tube. The backing tube is coaxially configured within an interior volume of the tubular target. A plurality of spaced apart grooves are disposed between the inner surface of the target and the outer surface of the backing tube, whereby each of the plurality of grooves extends along a periphery of the assembly. The grooves are configured to interlock with portions of the sputter target projecting therewithin to create a grooved interface.

In a second aspect, a method for forming a tubular sputter target assembly is provided comprising the steps of providing a cylindrical backing tube comprising a nonplanar outer surface and a plurality of separate and distinct grooves situated along the nonplanar outer surface, whereby the grooves extend along an end portion of the backing tube. A tubular target blank is also provided comprising a nonplanar inner surface. The target blank is positioned over the backing tube. The target blank and the backing tube are fed through a die. An outer diameter of the target blank is reduced, whereby a portion of an inner diameter of the target partially at least protrudes into the grooves of the backing tube to lock the target blank therein.

The objects and advantages of the invention will be better understood from the following detailed description of the preferred embodiments thereof in connection with the accompanying figures wherein like numbers denote same features throughout and wherein:

### BRIEF DESCRIPTION OF DRAWINGS

FIG. 1 shows a cross-sectional end view of a tubular target assembly in accordance with an embodiment of the invention;

FIG. 2 shows a cross-sectional end view of an alternative tubular target assembly in accordance with an embodiment of the invention;

FIG. 3 shows an alternative groove design having rounded edges characterized by a height, weight and depth of specific dimensional proportions;

FIG. 4 shows a cross-sectional end view of a backing tube positioned within a tubular target blank and prior to attachment thereto;

FIG. 5 shows a side view of the tubular target blank and the inner backing tube of FIG. 4 co-drawn in accordance with an embodiment of the invention to form a grooved interface;

FIG. 6 shows a temperature profile of a rotary target surface as a function of powder density levels that were ramped up during a sputtering process;

FIG. 7 shows a test set up for performing bend testing of targets; and

FIGS. 8-12 show bend tests of the inventive rotary target assembly having a grooved interface and monolithic extruded tubular targets.

### DETAILED DESCRIPTION OF THE INVENTION

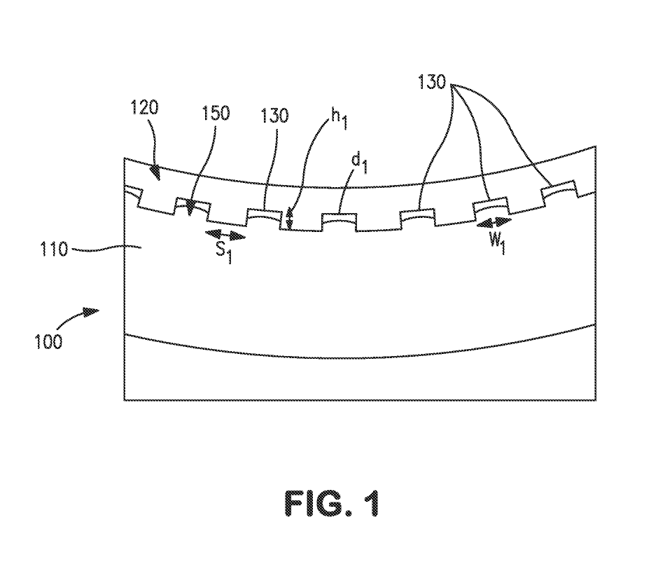

One aspect that embodies the principles of the present invention will now be described. FIG. 1 shows a cross-sectional end view of a rotary target assembly 100. The assembly 100 comprises an outer tubular target 110 directly bonded to an inner backing tube 120 to create a grooved interface 150. The grooved interface 150 is created by material along the inner diameter of the target 110 partially extending or protruding into grooves 130 located along a periphery of the backing tube 120. The target 110 is secured and locked to the backing tube 120 at the grooved interface 150.

The tubular target 110 comprises an inner surface that is in direct contact with the outer surface of the backing tube 120. The backing tube 120 is coaxially configured within an interior volume of the tubular target 110 to form the resultant rotary target assembly 100.

As will be explained in greater detail below, the locking arrangement is created by co-extruding or co-drawing the target 110 to the backing tube 120. During the co-extrusion or co-drawing process, the backing tube 120 is positioned within the outer tubular target 110. The periphery of the backing tube 120 contains multiple grooves 130. Both tubes 110 and 120 are fed through a die. The opening of the die has a diameter that is smaller than the outer diameter of the tubular target 110. As a result, when the target 110 is fed through the die, the outer tubular target 110 undergoes a reduction in its internal and outer diameters. At least a portion of the target material flows radially inward to at least partially fill the grooves 130 located along the inner backing tube 120.

The inner backing tube 120 is preferably formed from a harder material than the outer tubular target 110. The harder inner backing tube 120 provides structural rigidity to the outer tubular target 110 during the sputtering process. The harder inner backing tube 120 also enhances the ability of the softer material of the target 110 to be pushed radially inwards towards the grooves 130 of the inner backing tube 120 during the co-extrusion or co-drawing. As a result, at least a portion of the target 110 material is filled into the grooves 130. Generally, the inner backing tube 120 is composed of a thermally conductive material capable of transferring heat from the tubular target 110 that is generated during the sputtering operation. In a preferred embodiment, the backing tube 120 is formed from aluminum alloy and the outer tubular target 110 is formed from pure aluminum. In addition to pure aluminum target/aluminum alloy backing tube assemblies, it should be understood that the present invention also contemplates the selection of other types of materials, such as, for example, pure tantalum, pure copper, pure titanium and pure aluminum alloys. Different pairs of such materials can be used to form the bonded assembly. For example, a backing tube formed from titanium can be bonded to a tubular target formed from pure copper or pure aluminum alloys. In each of these examples, the selection of materials is such that the outer tubular target 110 is preferably a softer, purer metallic material while the inner backing tube 120 is preferably a harder, alloyed metallic material. Various purity levels of the target materials are contemplated by the present invention, including, but not limited to 3N (i.e., 99.9%), 4N (i.e., 99.99%) and 5N (i.e., 99.999%).

In accordance with known techniques in the art, multiple grooves 130 are formed into the surface of the backing tube 120. The grooves 130 are formed prior to positioning the backing tube 120 within the tubular target 110. Referring to FIG. 1, the grooves 130 are characterized by a width, w₁, height, h₁, and depth, d₁ (extending into the plane of the page). Each of the grooves 130 has a w₁ that is greater than h₁ to create a rectangular-shaped configuration. The grooves 130 are shown separated from each other by a predetermined spacing, s₁. Suitable dimensions for w₁, h₁ and d₁ are dependent upon numerous factors, including the required bond strength and the required thermal conductivity.

Sufficient bond strength between the tubular target 110 and the backing tube 120 is related to the amount of target 110 material that fills into the grooves 130 to create the interlocking arrangement. Conversely, sufficient thermal conductivity is related to the amount of target 110 material at the grooved interface 150 between the target 110 and the grooved backing tube 120. In other words, increasing the spacing, s₁, between adjacent grooves 130 increases the amount of material at the interface available for sufficient thermal conductivity to occur. Accordingly, the suitable range of dimensions of s₁, w₁, h₁ and d₁ is preferably selected to achieve a balance between the required thermal conductivity and the required bond strength for a particular sputtering application.

Other design considerations, such as the number of grooves 130, may also affect the selection of s₁, w₁, h₁ and d₁. For example, reducing the number of grooves 130 along the inner backing tube 120 may require that the size of each groove 130 is increased to allow more target 110 material to fill into each of the grooves 130. In other words, the resultant volume of each groove 130 as characterized by w₁, h₁ and d₁ may be proportionately increased to accommodate an increased filling of target 110 material therein to produce adequate bond strength. Conversely, increasing the number of grooves 130 may require modifying w₁, h₁ and d₁ such that the resultant volume of each groove 130 is proportionately decreased since a decreased amount of target 110 material may be filled therein to produce adequate bond strength.

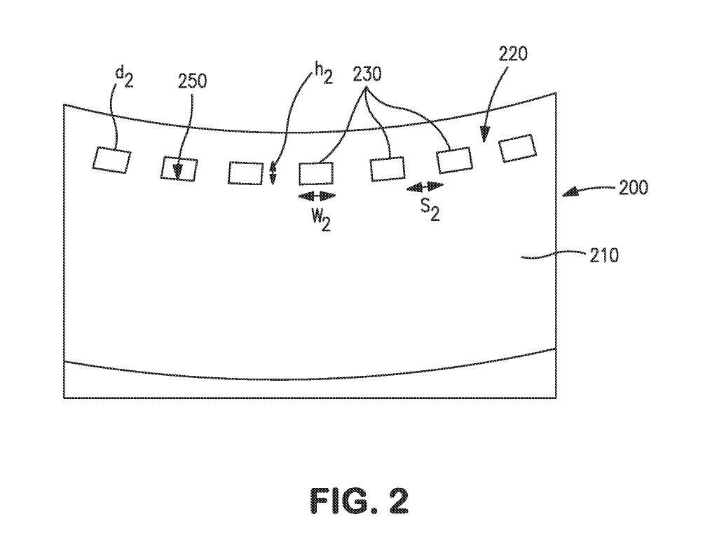

Various groove dimensions and shapes are contemplated. By way of example, FIG. 2 shows an alternative rotary target assembly 200 in which an inner backing tube 220 is locked into an outer tubular target 210 at a grooved interface 250. The grooved interface 250 is created by the extension or protrusion of target 210 material into grooves 230. Each of the grooves 230 is characterized by a predetermined s₂, w₂, h₂ and d₂. Each of the grooves 230 has a w₂ that is approximately equal to h₂ to create a square-shaped configuration. The square-shaped grooves 230 can be prepared along the periphery of the inner backing tube 210 in accordance with known techniques. In comparison to the grooves 130 of FIG. 1, the grooves 230 of FIG. 2 have a w₂ less than w₁, h₂ less than h₁ and s₂ less than s₁.

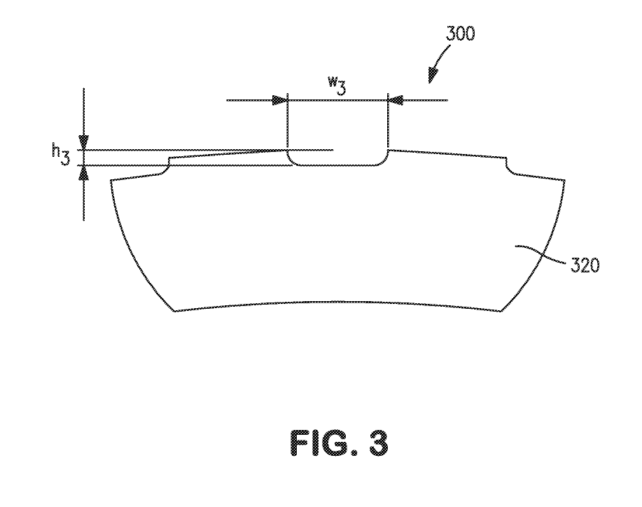

Other groove shapes are contemplated by the present invention. For example, the edges of the groove may be saw-tooth shaped or circular-shaped. Alternatively, the grooves can have rounded edges, as shown in FIG. 3. FIG. 3 shows a backing tube 320 with a groove 300 along a periphery thereof. For purposes of clarity, the corresponding outer tubular target is not shown. The groove 300 is characterized by a height, h₃, and width, w₃ and depth (extending into the plane of the page). The bottom of the groove 300 is shown to be a flat surface. Portions of the corresponding tubular target at least partially fill into the groove 300 during a co-extrusion or co-drawing process. The selection of a suitable groove shape is dependent upon numerous factors, including the requisite fill of the target material therein needed to achieve an adequate grooved interface between the target and backing tube as well as the specific sputtering application and the thermal and mechanical stresses associated therewith.

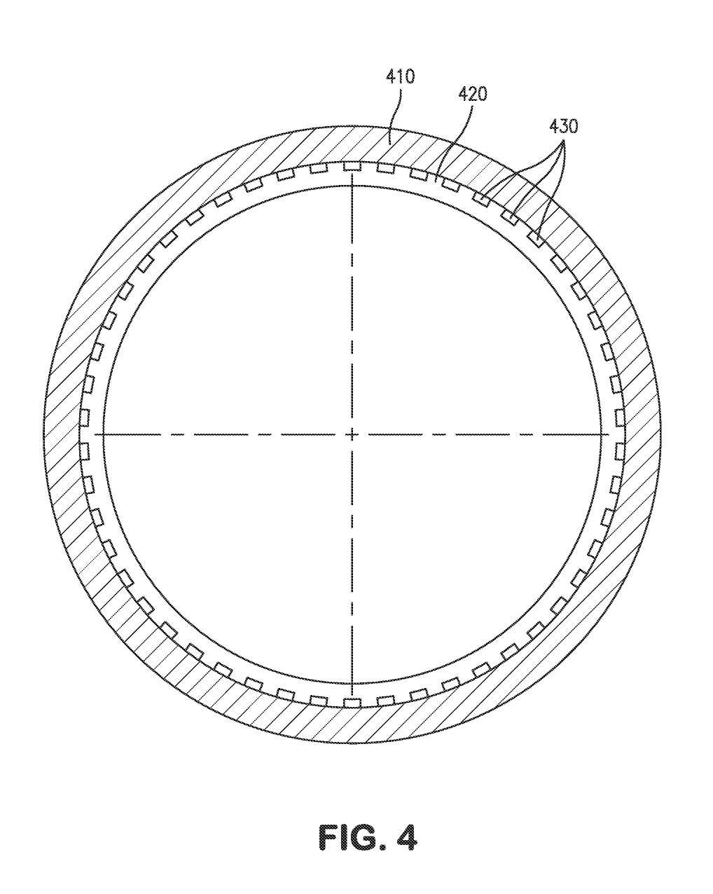

FIG. 4 shows a cross-sectional end view of an outer tubular target blank 410 that is positioned over an inner backing tube 420 prior to formation of a grooved interface there between. In this embodiment, a total of 50 grooves 430 are shown to extend about the backing tube 420. The grooves 430 are shown equally spaced about the entire periphery of the inner backing tube 420. The outer diameter of the inner backing tube 420 corresponds approximately to the inner diameter of the tubular target blank 410. In an alternative arrangement, a predetermined gap may exist between the outer diameter of the backing tube 420 and the inner diameter of the tubular target bank 410 prior to co-drawing or co-extrusion of the tubes 410 and 420.

The target blank 410 may be a component that is pre-formed by extrusion. In one example, the target blank 410 is preferably a pure aluminum blank tube that is formed from a pure aluminum billet or ingot. The backing tube 420 may also be a pre-formed component. In particular, the backing tube 420 is preferably extruded to the dimension of the final target assembly as it does not undergo a substantial change in length, diameter or wall thickness during the co-drawing or co-extrusion process. The grooves 430 can be machined into the backing tube 420 after the tube 420 is pre-formed. Alternatively, the grooves 430 can be extruded directly into the backing tube 420 when the backing tube 420 is pre-formed by extrusion. Other techniques for preparing the grooves 430 are contemplated by the present invention. The backing tube 420 is preferably formed from an aluminum alloyed series having acceptable corrosion resistance and mechanical strength to undergo sputtering.

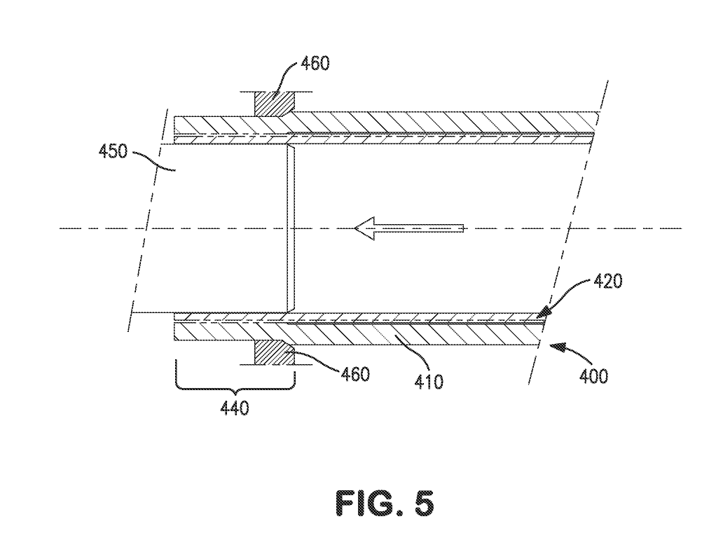

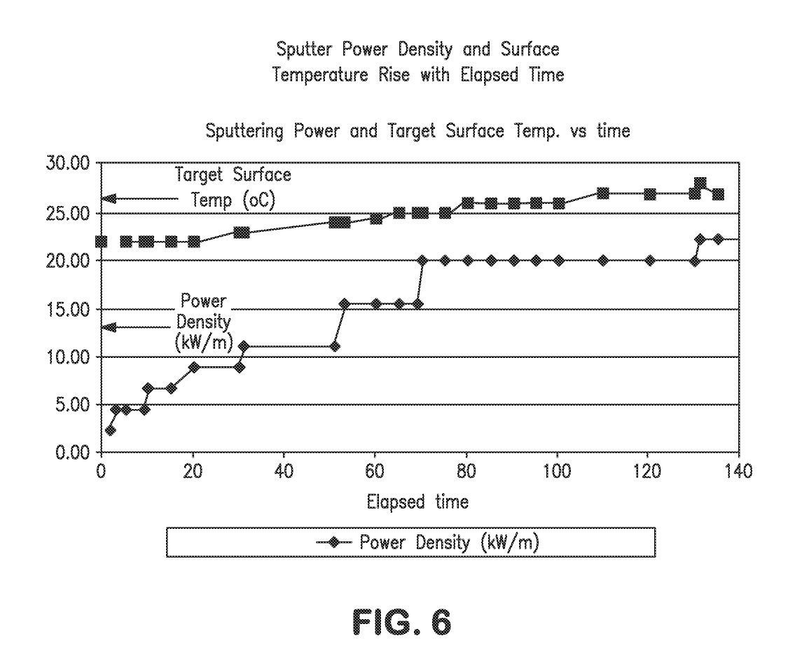

The target blank 410 is preferably thicker than the inner backing tube 420, as shown in FIGS. 4 and 5. Various thicknesses of the backing tube 420 and target blank 410 are contemplated. Selection of a suitable thickness for the backing tube 420 may depend on various factors, including, for example, the amount of structural rigidity required during the sputtering process and the desired electrical and thermal conductivities. Selection of a suitable thickness for the target blank 410 may likewise depend on various factors, including, for example, the amount of material required to be filled into the grooves 430 to produce a desired bond strength.

An exemplary method for interlocking a target blank to a backing tube will now be explained in accordance with a co-drawing process. Referring to FIG. 4, having positioned the inner backing tube 420 and outer tubular target blank 410 as shown, the tubes 410 and 420 can now be interlocked together by a co-drawing process. FIG. 5 shows an example of a co-drawing method to form a grooved interface that interlocks the tubes 410 and 420. The inner backing tube 420 is coaxially positioned inside of the tubular target blank 410 in a similar manner as shown in FIG. 4. The coaxially configured tubes 410 and 420 are then pulled through a die 460 in the direction indicated by the arrow. The inner backing tube 420 extends over a supporting mandrel 450. The outer diameter of the mandrel 450 is substantially the same as the inner diameter of the backing tube 410. As a result, the mandrel 450 maintains the shape and size of the inner diameter of the backing tube 420. The inner backing tube 420 has an outer diameter that is less than the opening of the die 460 so that the inner backing tube 420 does not undergo substantial reduction in diameter during formation of the grooved interface (e.g., grooved interface 150 or 250 of FIGS. 1 and 2, respectively).

The outer diameter of the tubular target blank 410 is greater than the opening of the die 460, thereby causing the blank 410 to undergo a reduction in diameter as it is pulled through the die 460. Specifically, the outer and inner diameters of the target blank 410 are reduced with a corresponding decrease in wall thickness as the blank 410 and inner backing tube 420 are pulled or drawn through the die 460. Frictional resistance is generated between the outer surface of the tubular blank 410 and the surface of the die 460 and between the inner surface of the tubular blank 410 and the outer surface of backing tube 420. The drawing is performed against the frictional forces. As a result, tension is generated in a longitudinal direction of the tube blank 410. Portions of the target blank 410 material become pushed inwards towards the grooves 430 (FIG. 4) located along the periphery of the inner backing tube 420. The softer target blank 410 can penetrate into the harder backing tube 420 to at least partially fill the grooves 430 contained there along. Without being bound by any theory, the filling process may be facilitated by the softer target blank 410 material pressing up against the rigid backing tube 420, which subsequently directs the target 410 material to flow into the grooves 430 of the backing tube 420. The filling of the grooves 430 may also promote localized deformation at the interface to create the grooved interface. Region 440 is representative of that portion of the backing tube 420 and tubular target 410 that has been interlocked to form the grooved interface (e.g., grooved interface 150 or 250 of FIGS. 1 and 2, respectively).

The pressure applied during the co-drawing may vary over a wide range. The pressure and time required are controlled by adequate formation of an interlocked grooved interface in which the grooves 430 are at least partially filled with the softer target 410 material. The amount of filling of target material into the grooves of the backing tube 420 is optimized to achieve sufficient bond strength at the grooved interface without compromising the necessary thermal conductivity required to effectively dissipate heat from the surface of the target 410 during a sputtering process. In one embodiment, each of the plurality of grooves is at least 15% filled with the deformed target blank material.

There are several advantages of the co-drawing process for fabrication of the rotary target assembly. For example, there is low level oxidation and high strength due to working the target and backing tube at room temperature in comparison to hot extrusion and other hot processes. Additionally, there is relatively greater control of microstructure compared to hot and thermal heterogeneous assembly processes. There is no disturbance in the metallurgical structure of either the target or the backing tube when constructed in accordance with the embodiments of the present invention. As a result, the assembly maintains its metallurgical integrity.

Further, the fabrication process in accordance with the present invention is simplified. The ability to directly bond the target and backing tube materials eliminates the cost, time and complexity of various assembly methods such as solder-bonding the active part of the target onto a backing tube with an interlayer material in combination with specific surface treatment of the inner side of the active part of the target to prevent corrosion. In addition, conventional co-extrusion and co-drawing processes require the target material to undergo substantially more deformation to create the bonded interface, which typically translates into a more energy intensive and costly fabrication process. Accordingly, the reduction in required deformation created by the present invention can be advantageous when employing materials which are difficult to deform. Significantly less reduction in thickness is required to create a grooved interface. The presence of the grooves reduces the pressure required to form the grooved interface between the target and backing tube in comparison to conventional co-extrusion and co-drawing processes.

The resultant bond strength, as characterized by the grooved interface, can be evaluated through tensile strength or shear strength testing. The resultant bond does not cause warping and is capable of withstanding thermal and mechanical stresses typically incurred during a sputtering operation. The grooved interface increases the resistance of the bonded assembly to failure. This resistance allows for use of higher power density levels (i.e., higher sputtering temperatures) and extends the range of target sizes achievable without compromising structural reliability.

The target blank 410 material can also fill the grooves 430 with a co-extrusion process. In the co-extrusion process, the target blank 410 and the backing tube 420 are pushed through a die 460 by a ram. The ram slides onto a needle, which fits within the inner diameter of the backing tube 420. Movement of the needle is dependent upon movement of the ram. As the ram is pushed, the needle pushes the backing tube 420 and target blank 410 pre-assembly through the die 460. An axial pressing force is generated as the outer diameter of the target blank 410 presses against the inner portion of the die 460. The axial pressing force causes material of the target blank 410 to compress three-dimensionally and plastically deform. As a result, a plastic flow of the target blank 410 material fills at least a portion of the grooves 430.

### EXAMPLE 1

A rotary target assembly was made according to the principles of the present invention. The tubular target blank was formed from 5N pure aluminum. Approximately 50 rectangular-shaped grooves were machined along the periphery of the backing tube. The backing tube was then positioned coaxially within the inner diameter (ID) of the tubular target blank and co-drawn through a die. A grooved interface as shown in FIG. 1 was formed. Approximately 50% to 100% of the groove space was filled with the target material. The spacing between the grooves was approximately 5 mm. The height of the grooves was approximately 0.7 mm. The width of the grooves was 5 mm. The rotary target assembly was then inserted into a rotary test rig to simulate sputtering conditions. The rotary test rig that was utilized in the test was a cylindrical stainless steel vacuum chamber with an ID of 10.25 inches and a height of 25 inches. After the rotary target assembly was installed in the vacuum chamber, the chamber was pumped down. After pumping down, the chamber was back-filled with argon and DC power was applied to the target assembly to initiate sputtering while a DC power rotated the target assembly and the magnetron at a constant speed. Temperature measurements on the target assembly surface were taken at various power density levels.

Power density levels in the test rig were ramped upwards throughout the sputtering process from about 3 kW/m up to about 23 kW/m. The test was about 140 hours in duration. The target surface temperature exhibited a low surface temperature rise during the duration of the 140 hours of sputtering, indicating that the structural integrity of the grooved interface was preserved. Consequently, heat was effectively being dissipated away from the grooved interface towards the cooling water channels located within the backing tube. After the power was shut off, the end-of-life rotary target assembly was removed from the test rig. No significant debonding or warpage was observed. The grooved interface exhibited sufficient bond strength and thermal conductivity and was capable of withstanding the thermal and mechanical stresses generated during the sputtering process.

### EXAMPLE 2

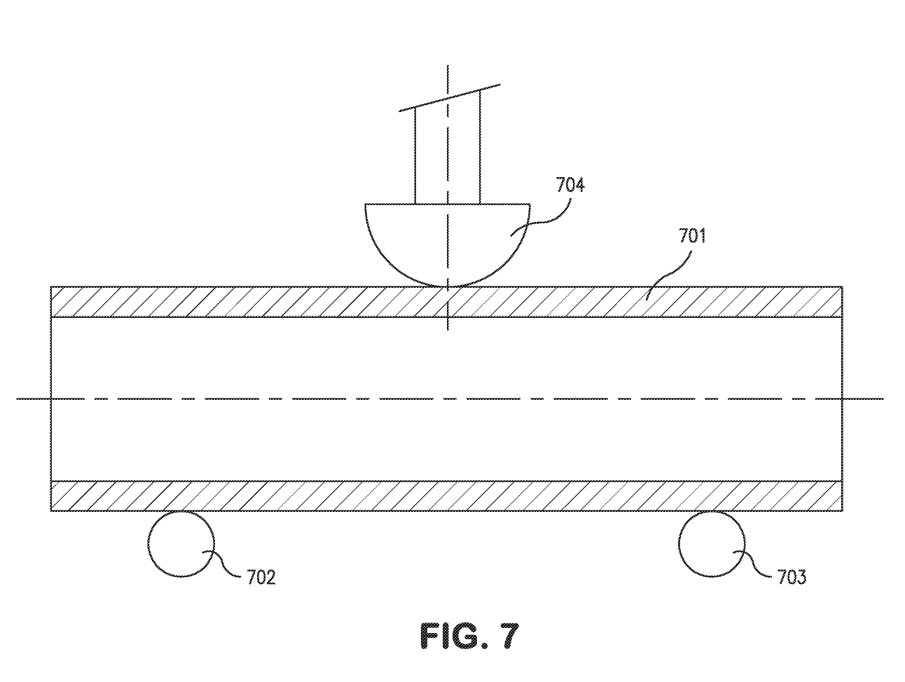

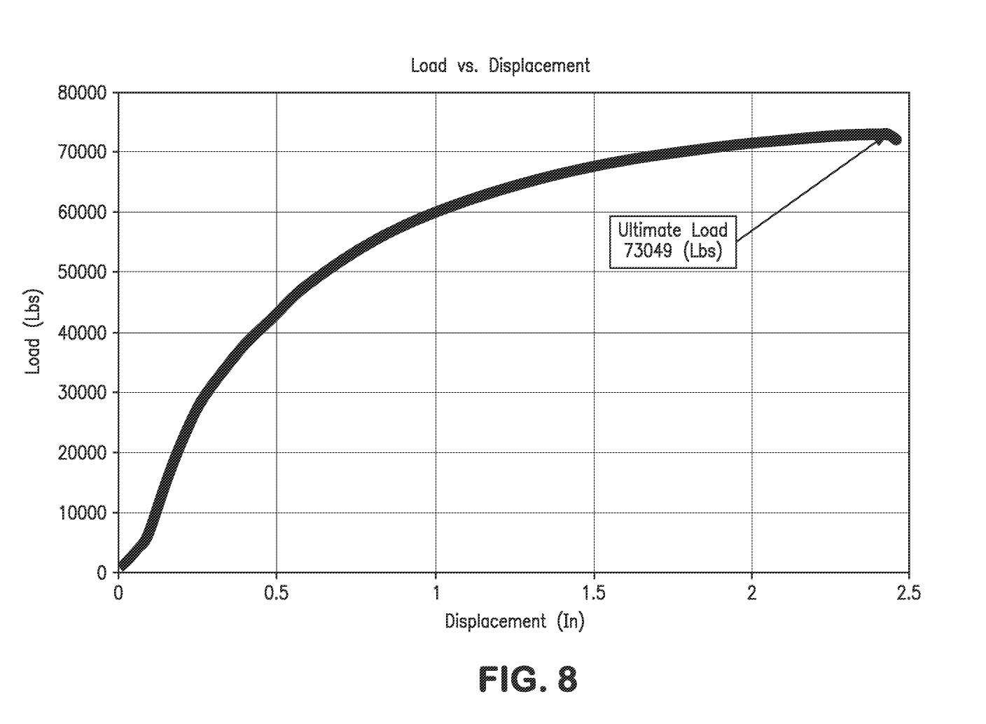

A rotary tubular target assembly was formed as described in Example 1. A portion of the assembly was cut to obtain a sample of necessary size for bend testing. The sample had an outer diameter of 173 mm, an inner diameter of 125 mm and a length of 610 mm. The sample was bend tested by Westmoreland Mechanical Testing and Research, Inc. in Youngstown, Pa. A schematic of the test set up utilized by Westmoreland is shown in FIG. 7. The test set up is routinely employed in the industry to evaluate strength and rigidity of materials. The sample target assembly 701 was placed onto two support pins 702 and 703. Each of the support pins 702 and 703 had a diameter of 2 inches. The pins 702 and 703 were spaced apart from each other a distance of 16 inches as measured from center-to-center of the pins 702 and 703. A load mechanism 704, as shown in FIG. 7, was positioned directly above the midpoint of the pins 702 and 703. The load mechanism 704 consisted of a half-cylindrical shaped member having a radius of 5 inches. The initial position of the load member 704 was zeroed out and considered the starting position. From the starting position, the load member 704 was advanced downwards towards the sample tube 701 so as to push against the sample tube 701. The displacement of the load member 704 was measured as a function of the load it exerted against the sample tube 701. The total distance that the load member 704 travelled from the starting position to within the sample tube 701 represents the displacement of the tube 701. The test was completed after the ultimate load was achieved. Displacement of the load member 704 along with corresponding load and load time were measured. The data was collected and saved. The results of the bend test for the assembly were measured and reported by Westmoreland in FIG. 8. For the sample tube 701 of this test, the ultimate load achieved was 73,049 lbs. At this load, the displacement of the load member was about 2.4 inches.

### COMPARATIVE EXAMPLE 2

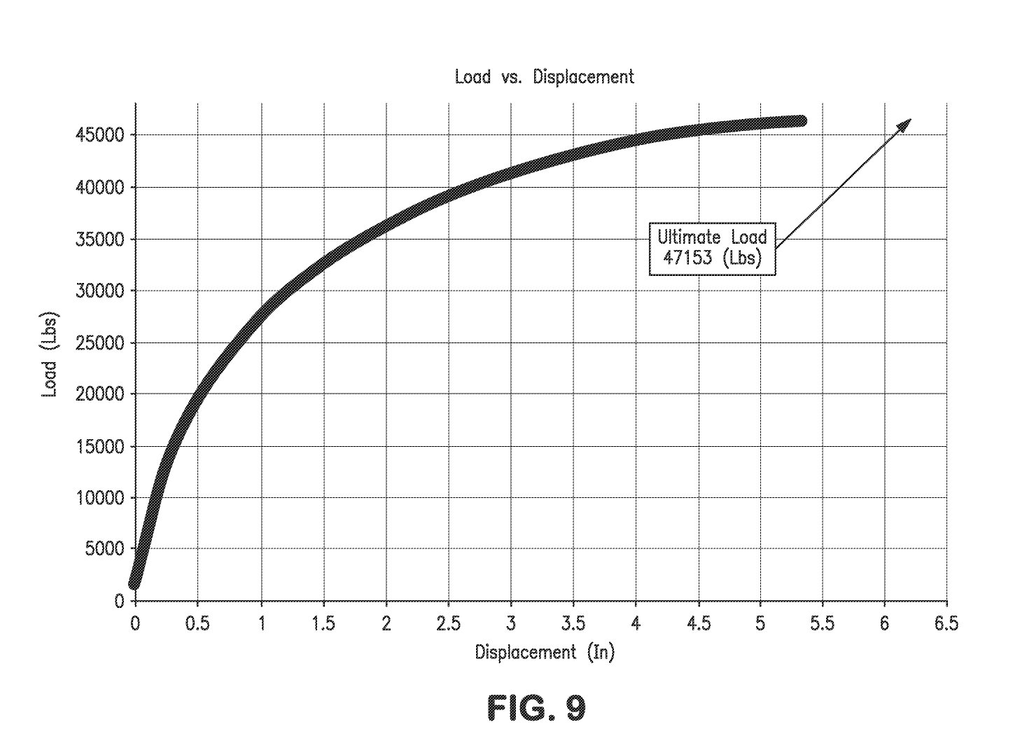

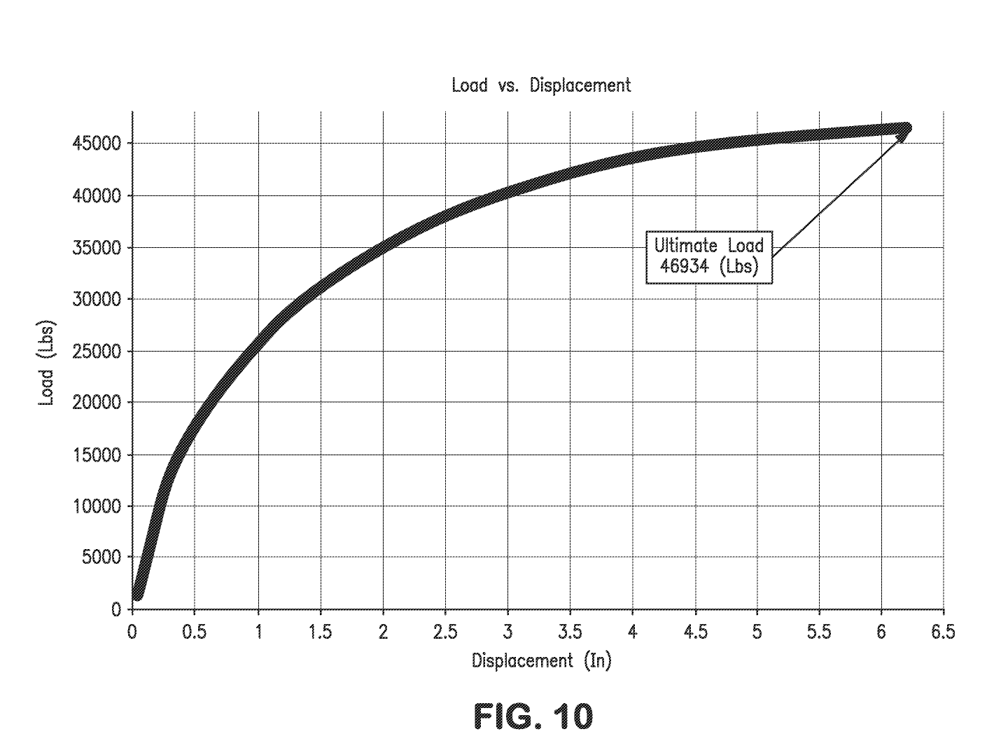

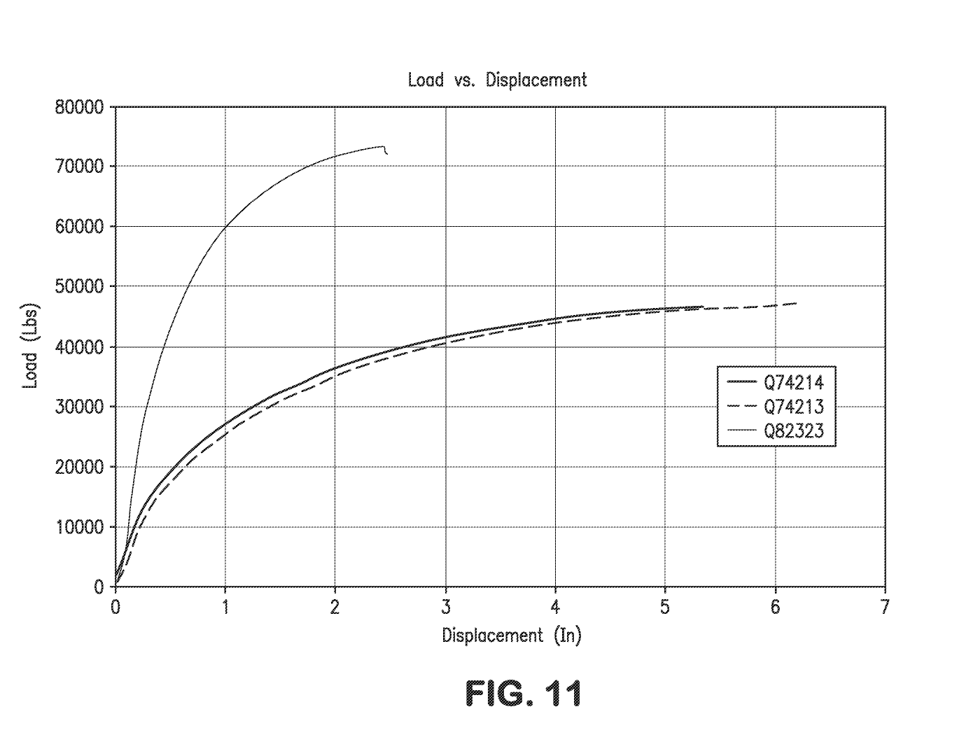

The same bend test as that of Example 2 was conducted with two conventional samples, each of which was a monolithic 5N pure aluminum extruded tube. The monolithic extruded tubes had the same inner diameter, outer diameter and length as the co-drawn tube of Example 2. Results of the bend test were collected and are shown at FIGS. 9 and 10. The ultimate load achieved was significantly less than that of the inventive co-drawn tube shown in FIG. 8. Specifically, FIG. 9 shows that an ultimate load of 47,153 lbs was achieved at a displacement of about 5.3 inches. FIG. 10 shows that an ultimate load of 46,934 lbs was achieved at a displacement of about 6.4 inches. The conventional samples deformed significantly more at lower loads compared to the co-drawn tubular target assembly of FIG. 8. The increased improvement of the co-drawn target assembly of FIG. 8 can be visually seen in FIG. 11, which graphically shows the bend testing results for all of the samples.

The results demonstrated that the target assembly of the present invention had superior bond strength and stiffness as well as superior material modulus, relative to the conventional extruded tubes. The improved properties were attributed to the grooved interface of the present invention.

While it has been shown and described what is considered to be certain embodiments of the invention, it will, of course, be understood that various modifications and changes in form or detail can readily be made without departing from the spirit and scope of the invention. It is, therefore, intended that this invention not be limited to the exact form and detail herein shown and described, nor to anything less than the whole of the invention herein disclosed and hereinafter claimed.

1. A rotatable sputter target assembly comprising:
a backing tube comprising an outer surface;
a sputtering tubular target comprising an inner surface, the inner surface in direct contact with the outer surface of the backing tube, wherein the backing tube is coaxially configured within an interior volume of the tubular target; and
a plurality of spaced apart grooves disposed between the inner surface of the target and the outer surface of the backing tube, whereby each of the plurality of grooves extends along a periphery of the assembly, the grooves configured to interlock with portions of the sputter target projecting therewithin to create a grooved interface.

2. The assembly of claim 1, wherein the backing tube comprises a first material, the target comprises a second material and the plurality of spaced apart grooves is disposed along the first material.

3. The assembly of claim 1, wherein the plurality of spaced apart grooves extend along the outer surface of the backing tube, and further wherein portions of an inner surface of the tubular target protrude into least a portion of each of the plurality of grooves.

4. The assembly of claim 1, wherein the assembly comprises a bond strength sufficient to eliminate warpage of the assembly during sputtering.

5. The assembly of claim 1, wherein each of the plurality of spaced apart grooves is characterized by a predetermined shape, height, depth and width.

6. The assembly of claim 1, wherein the grooves are selected from the group consisting of square, rectangular, saw-tooth and circular shapes.

7. The assembly of claim 1, wherein the sputtering tubular target is configured to be sputtered at a power density level of up to about 20 kW/m without debonding.

8. The assembly of claim 1, wherein the rotatable sputter target assembly is characterized by an ultimate load of about 73000 lbs.

9. The assembly of claim 1, wherein the target blank and the backing tube are formed from a material selected from the group consisting of pure aluminum, pure tantalum, pure copper, pure titanium and high and medium purity aluminum alloys.

10. A method for forming a tubular sputter target assembly comprising the steps of:
providing a cylindrical backing tube comprising a nonplanar outer surface and a plurality of separate and distinct grooves situated along the nonplanar outer surface, whereby the grooves extend along an end portion of the backing tube;
providing a tubular target blank comprising a nonplanar inner surface;
positioning the target blank over the backing tube;
feeding the target blank and the backing tube through a die; and
reducing an outer diameter of the target blank, whereby a portion of an inner diameter of the target partially at least protrudes into the grooves of the backing tube to lock the target blank therein.

11. The method of claim 10, wherein the portion of the target blank is mechanically deformed into the grooves.

12. The method of claim 10, wherein each of the plurality of grooves is at least 15% filled with the deformed target blank material.

13. The method of claim 10, wherein the target blank and the backing tube are formed from a material selected from the group consisting of pure aluminum, pure tantalum, pure copper, pure titanium and high and medium purity aluminum alloys.

14. The method of claim 13, wherein the purity of the material of the target blank and the backing tube is 3N, 4N or 5N.

15. The method of claim 10, wherein the target blank is co-drawn with the backing tube.

16. The method of claim 10, wherein the target blank is co-extruded with the backing tube.
